(19) United States
(12) Patent Application Publication
(10) Pub. No.: US 2016/0131720 A1
(43) Pub. Date: May 12, 2016

(54) DEVICE FOR ESTIMATING STATE OF HEALTH OF BATTERY, AND STATE OF HEALTH ESTIMATION METHOD FOR BATTERY

(71) Applicants: CALSONIC KANSEI CORPORATION, Saitama (JP); KEIO UNIVERSITY, Tokyo (JP)

(72) Inventors: Atsushi BABA, Saitama-shi (JP); Shuichi ADACHI, Yokohama-shi (JP)

(73) Assignees: CALSONIC KANSEI CORPORATION, Saitama-shi (JP); KEIO UNIVERSITY, Minato-ku (JP)

(21) Appl. No.: 14/895,986

(22) PCT Filed: Jul. 11, 2014
(86) PCT No.: PCT/JP2014/003699

§ 371 Date: Dec. 4, 2015

(30) Foreign Application Priority Data
Sep. 5, 2013 (JP) 2013-184479

(51) Int. Cl. G01R 31/36; G01R 35/00

(52) U.S. Cl. CPC G01R 31/3679; G01R 31/3651; G01R 35/005

(57) ABSTRACT

A device for estimating state of health of battery, and a state of health estimation method with improved estimation accuracy of the state of health of the battery are provided. The device for estimating state of health includes: a charge and discharge current detection unit (1); a terminal voltage detection unit (2); a first state of charge estimation unit (4) configured to estimate a first state of charge; a second state of charge estimation unit (5) configured to estimate a second state of charge; a first state of health estimation unit (6); a second state of health estimation unit (7); and a first correction value calculation unit (9) configured to calculate a first correction value for correcting the first state of charge. The first state of charge estimation unit (4) is configured to correct the first state of charge using the first correction value.

### CROSS REFERENCE TO RELATED APPLICATION

This application claims priority to Japanese Patent Application No. 2013-184479 filed on Sep. 5, 2013, the entire disclosure of which is incorporated herein by reference.

### TECHNICAL FIELD

The disclosure relates to a device for estimating state of health of a battery and state of health estimation method for a battery for estimating the state of health of a battery used in an electric car or the like.

### BACKGROUND

Secondary cells which are rechargeable batteries have been conventionally used in electric cars and the like. To determine the distance that can be traveled by an electric car with such a battery, the current with which the battery can be charged and discharged, and the like, it is necessary to detect, for example, the state of charge (SOC) and state of health (SOH) of the battery which are the internal state quantities of the battery.

Since these internal state quantities cannot be directly detected, the current integration method (coulomb counting method) or the open circuit voltage estimation method (sequential parameter method) is employed. The current integration method estimates the state of charge (absolute state of charge (ASOC)), by detecting the charge and discharge current of the battery through time and integrating the current. The open circuit voltage estimation method estimates the state of charge (relative state of charge (RSOC)), by estimating the open circuit voltage of the battery using an equivalent circuit model of the battery. SOH is estimated by taking the ratio of the amount of change of ASOC and the amount of change of RSOC (for example, see Patent Document 1).

### CITATION LIST

### Patent Document

Patent Document 1: JP 2012-58028 A

### SUMMARY

### Technical Problem

However, there is, for example, a problem in that current sensor errors accumulate in ASOC calculated by the current integration method. This causes similar accumulation of errors in the state of health calculated using the amount of change of ASOC, and leads to lower estimation accuracy of the state of health.

It could be helpful to provide a device for estimating state of health of a battery and state of health estimation method for a battery with improved estimation accuracy of the state of health of the battery.

### Solution to Problem

A device for estimating state of health of a battery according to a first aspect includes: a charge and discharge current detection unit configured to detect a charge and discharge current value of the battery; a terminal voltage detection unit configured to detect a terminal voltage value of the battery; a first state of charge estimation unit configured to estimate a first state of charge by integrating the charge and discharge current value; a second state of charge estimation unit configured to estimate a second state of charge based on a relationship between an open circuit voltage value and a state of charge of the battery; a first state of health estimation unit configured to estimate a first state of health based on the first state of charge and the second state of charge; a second state of health estimation unit configured to estimate a second state of health based on a relationship between an internal resistance value and a state of health of the battery; and a first correction value calculation unit configured to calculate a first correction value for correcting the first state of charge, based on a difference between the first state of health and the second state of health, wherein the first state of charge estimation unit is configured to correct the first state of charge using the first correction value.

A state of health estimation device according to a second aspect further includes a second correction value calculation unit configured to calculate a second correction value for correcting the first state of charge or the second state of charge, based on a difference between the first state of charge and the second state of charge.

A device for estimating state of health according to a third aspect further includes a parameter estimation unit configured to estimate the open circuit voltage value of the battery from an equivalent circuit model of the battery, using the charge and discharge current value and the terminal voltage value, wherein the second state of charge estimation unit is configured to estimate the second state of charge based on the relationship between the open circuit voltage value and the state of charge, using the estimated open circuit voltage value.

In a device for estimating state of health according to a fourth aspect, the second state of charge estimation unit is configured to estimate the second state of charge based on the relationship between the open circuit voltage value and the state of charge, using the terminal voltage value.

A state of health estimation method according to a fifth aspect includes steps of: detecting a charge and discharge current value of the battery; detecting a terminal voltage value of the battery; estimating a first state of charge by integrating the charge and discharge current value; estimating a second state of charge based on a relationship between an open circuit voltage value and a state of charge of the battery; estimating a first state of health based on the first state of charge and the second state of charge; estimating a second state of health based on a relationship between an internal resistance value and a state of health of the battery; calculating a first correction value for correcting the first state of charge, based on a difference between the first state of health and the second state of health; and correcting the first state of charge using the first correction value.

### Advantageous Effect

The device for estimating state of health according to the first aspect corrects the current integration method state of charge, based on the difference between the first state of health estimated from the ratio of the amount of change of the current integration method state of charge (the first state of charge) and the amount of change of the open circuit voltage method state of charge (the second state of charge) and the second state of health estimated based on the relationship between the internal resistance value and state of health of the battery. This improves the estimation accuracy of the current integration method state of charge, and as a result improves the estimation accuracy of the state of health of the battery.

The device for estimating state of health according to the second aspect corrects the current integration method state of charge or the open circuit voltage method state of charge, based on the difference between the current integration method state of charge and the open circuit voltage method state of charge. This improves the estimation accuracy of the current integration method state of charge or the open circuit voltage method state of charge, and as a result further improves the estimation accuracy of the state of health of the battery.

The device for estimating state of health according to the third aspect estimates the open circuit voltage value of the battery using the equivalent circuit model of the battery, and estimates the open circuit voltage method state of charge using the estimated open circuit voltage value. This improves the estimation accuracy of the open circuit voltage method state of charge, and as a result further improves the estimation accuracy of the state of health of the battery.

The device for estimating state of health according to the fourth aspect detects the terminal voltage value of the battery, and estimates the open circuit voltage method state of charge using the detected terminal voltage value as the open circuit voltage value. Since there is no need to estimate the open circuit voltage value of the battery, the state of health can be estimated with reduced processing load.

The state of health estimation method according to the fifth aspect corrects the current integration method state of charge, based on the difference between the first state of health estimated from the ratio of the amount of change of the current integration method state of charge and the amount of change of the open circuit voltage method state of charge and the second state of health estimated based on the relationship between the internal resistance and state of health of the battery. This improves the estimation accuracy of the current integration method state of charge, and as a result improves the estimation accuracy of the state of health of the battery.

### BRIEF DESCRIPTION OF THE DRAWINGS

In the accompanying drawings:

FIG. 1 is a block diagram schematically illustrating the structure of a device for estimating state of health according to Embodiment 1;

FIG. 2 is a block diagram schematically illustrating the structure of a device for estimating state of health in which some of the structural elements in the device for estimating state of health in FIG. 1 have been removed;

FIGS. 3(a), 3(b), and 3(c) are diagrams for describing the state of health estimation result by the device for estimating state of health according to Embodiment 1;

FIG. 4 is a block diagram schematically illustrating the structure of a device for estimating state of health according to Embodiment 2;

FIG. 5 is a block diagram schematically illustrating the structure of a device for estimating state of health according to Modification 1; and

FIG. 6 is a block diagram schematically illustrating the structure of a device for estimating state of health according to Modification 2.

### DETAILED DESCRIPTION

The following describes embodiments.

### Embodiment 1

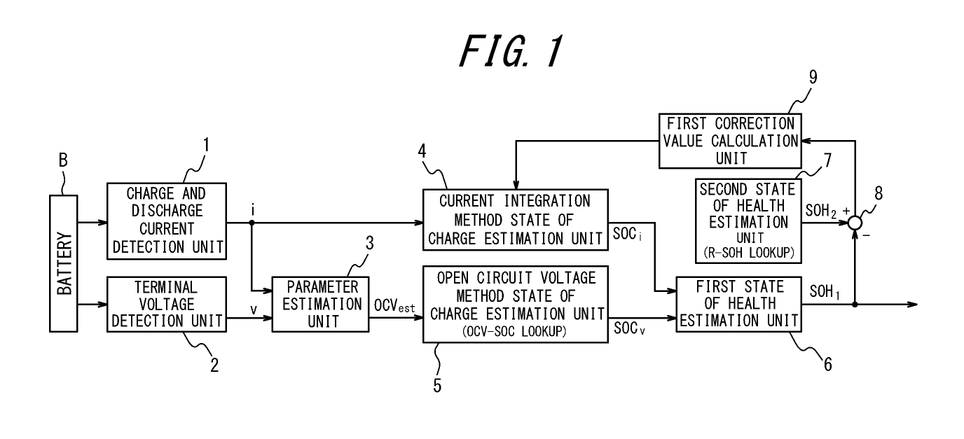

FIG. 1 is a block diagram of a device for estimating state of health of a battery according to Embodiment 1. The device for estimating state of health of a battery according to Embodiment 1 includes a charge and discharge current detection unit 1, a terminal voltage detection unit 2, a parameter estimation unit 3, a current integration method state of charge estimation unit (first state of charge estimation unit) 4, an open circuit voltage method state of charge estimation unit (second state of charge estimation unit) 5, a first state of health estimation unit 6, a second state of health estimation unit 7, a first subtraction unit 8, and a first correction value calculation unit 9. A battery B is connected to the device for estimating state of health. An overview of the device for estimating state of health of a battery according to Embodiment 1 is as follows. The first correction value calculation unit 9 calculates a first correction value for correcting a current integration method state of charge, based on the difference between a first state of health SOH₁ and a second state of health SOH₂ estimated respectively by the first state of health estimation unit 6 and the second state of health estimation unit 7. The current integration method state of charge estimation unit 4 corrects the current integration method state of charge, using the calculated first correction value.

The battery B is a rechargeable battery. The following description assumes that the battery B is a lithium ion battery. The battery B is, however, not limited to a lithium ion battery, and may be any of the other types of batteries such as a nickel metal hydride battery.

The charge and discharge current detection unit 1 detects the value of discharge current in the case where the battery B supplies power to an electric motor (not illustrated) or the like. The charge and discharge current detection unit 1 also detects the value of charge current in the case where the battery B recovers part of braking energy from the electric motor functioning as a power generator during braking or is charged from a ground power source. For example, the charge and discharge current detection unit 1 detects a charge and discharge current value i flowing through the battery B using a shunt resistor or the like. The charge and discharge current detection unit 1 supplies the detected charge and discharge current value i to both of the parameter estimation unit 3 and the current integration method state of charge estimation unit 4, as an input signal. The charge and discharge current detection unit 1 is not limited to the above-mentioned structure, and may have any of various structures and forms as appropriate.

The terminal voltage detection unit 2 detects the value of voltage between the terminals of the battery B. The terminal voltage detection unit 2 supplies the detected terminal voltage value v to the parameter estimation unit 3. The terminal voltage detection unit 2 may have any of various structures and forms as appropriate.

The parameter estimation unit 3 estimates each parameter in an equivalent circuit model of the battery B, based on the charge and discharge current value i and terminal voltage value v received respectively from the charge and discharge current detection unit 1 and terminal voltage detection unit 2. In detail, the parameter estimation unit 3 estimates a capacitance C of a capacitor, an internal resistance R, and an open circuit voltage (OCV) OCVₑₛₜ based on the method of least squares as an example, using an equivalent circuit model of the battery B including a capacitor and an internal resistor. The equivalent circuit model of the battery B may be any mathematical model representing the inside of the battery.

The current integration method state of charge estimation unit 4 estimates a current integration method state of charge (first state of charge) SOCᵢ. In detail, the current integration method state of charge estimation unit 4 estimates SOCᵢ as a state variable, by integrating the charge and discharge current value i received from the charge and discharge current detection unit 1. The current integration method state of charge estimation unit 4 then corrects SOCᵢ based on the first correction value received from the first correction value calculation unit 9. The process of correcting SOCᵢ will be described in detail later.

The open circuit voltage method state of charge estimation unit 5 estimates an open circuit voltage method state of charge (second state of charge) SOCᵥ. In detail, the open circuit voltage method state of charge estimation unit 5 stores the relationship between the open circuit voltage and the state of charge determined by experiment beforehand, in an OCV−SOC lookup table. The open circuit voltage method state of charge estimation unit 5 estimates the state of charge corresponding in the lookup table to the estimated open circuit voltage OCVₑₛₜ received from the parameter estimation unit 3, as SOCᵥ.

The first state of health estimation unit 6 estimates the first state of health SOH₁, based on SOCᵢ estimated by the current integration method state of charge estimation unit 4 and SOCᵥ estimated by the open circuit voltage method state of charge estimation unit 5. In detail, the first state of health estimation unit 6 estimates SOH₁ from the ratio of the amount of change ΔSOCᵢ of the current integration method state of charge and the amount of change ΔSOCᵥ of the open circuit voltage method state of charge from when the measurement of the battery B starts, as shown in Expression (1):

SOH₁=ΔSOCᵢ/ΔSOCᵥ=(SOCᵢ−SOC₀)/(SOCᵥ−SOC₀) (1).

Here, SOC₀ is the state of charge when the measurement of the battery B starts. For example, SOC₀ can be determined by any method, such as measuring the terminal voltage value v₀ of the battery B when the measurement of the battery B starts and checking the OCV−SOC lookup table using the measured terminal voltage value v₀.

The second state of health estimation unit 7 estimates the second state of health SOH₂, based on the relationship between the internal resistance value and state of health of the battery B. In detail, the second state of health estimation unit 7 stores the relationship between the internal resistance and state of health of the battery B determined by experiment beforehand, in an R−SOH lookup table. The second state of health estimation unit 7 estimates the state of health corresponding in the lookup table to the internal resistance value R of the battery B estimated by the parameter estimation unit 3, as SOH₂.

The first subtraction unit 8 subtracts SOH₁ estimated by the first state of health estimation unit 6 from SOH₂ estimated by the second state of health estimation unit 7.

The first correction value calculation unit 9 calculates the first correction value, by multiplying the difference (SOH₂−SOH₁) of the state of health received from the first subtraction unit 8 by a Kalman gain. The first correction value calculation unit 9 supplies the calculated first correction value to the current integration method state of charge estimation unit 4.

The process of calculating the first correction value and the process of correcting SOCᵢ are described below. These processes use, for example, a Kalman filter. The Kalman filter designs a model of a target system, and compares the respective outputs in the case where the same input signal is supplied to the model and the actual system. If the outputs are different, the Kalman filter multiplies the difference by the Kalman gain and feeds it back to the model, thus correcting the model so as to minimize the difference. The Kalman filter repeatedly performs this operation to estimate the true internal state quantity.

Suppose, in the Kalman filter, the observation noise is Gaussian white noise. In such a case, the parameter of the system is a stochastic variable, so that the true system is a stochastic system. Hence, the observation value is described by a linear regression model, and the sequential parameter estimation problem is able to be formulated using state space representation. This enables the estimation of the time-variant parameter without recording the sequential state. It is thus possible to generate such a mathematical model that can be determined as identical to the target for a predetermined purpose from the measurement of input and output data of the target dynamic system. In other words, system identification is possible.

Consider the following discrete system in the Kalman filter:

xₖ₊₁f(xₖ)+bᵤ(uₖ)+bυₖ (2)

yₖ=h(xₖ, uₖ)+ωₖ (3).

Here, x is the state variable, y is the observation value, u is the input, and k is the time of discrete time. Meanwhile, υ and ω are system noise and observation noise independent of each other, namely, N(0, συ²) and N(0, σω²).

For the above-mentioned system, the Kalman filter estimates the state variable x by the following algorithm:

$$\begin{matrix}[ Math . 1 ] & \\ {\hat{x}}_{k + 1 \vert k} = f ( {\hat{x}}_{k \vert k} ) + {b}_{u} ( {u}_{k} ) + b {υ}_{k} & ( 4 ) \\ {P}_{k + 1 \vert k}^{xx} = {A}_{k} {P}_{k \vert k}^{xx} {A}_{k}^{T} + {σ}_{υ}^{2} {bb}^{T} & ( 5 ) \\ {A}_{k} ≡ \frac{\partial f ( x )}{\partial x} {\vert}_{x = {\hat{x}}_{k \vert k}} & ( 6 ) \\ {\hat{y}}_{k + 1 \vert k} = {h}_{d} ( {\hat{x}}_{k + 1 \vert k} , {u}_{k} ) & ( 7 ) \\ {P}_{k + 1 \vert k}^{yy} = {C}_{k + 1} {P}_{k + 1 \vert k}^{xx} {C}_{k + 1}^{T} + {σ}_{ω}^{2} & ( 8 ) \\ {P}_{k + 1 \vert k}^{xy} = {P}_{k + 1 \vert k}^{xx} {C}_{k + 1}^{T} & ( 9 ) \\ {C}_{k + 1} ≡ \frac{\partial h ( x )}{\partial x} {\vert}_{x = {\hat{x}}_{k + 1 \vert k}} & ( 10 ) \\ {K}_{k + 1} = {{P}_{k + 1 \vert k}^{xy} ( {P}_{k + 1 \vert k}^{yy} )}^{- 1} & ( 11 ) \\ {P}_{k + 1 \vert k + 1}^{xx} = {P}_{k + 1 \vert k}^{xx} + {K}_{k + 1} {P}_{k + 1 \vert k}^{yy} {K}_{k + 1}^{T} & ( 12 ) \\ {\hat{x}}_{k + 1 \vert k + 1} = {\hat{x}}_{k + 1 \vert k} + {K}_{k + 1} ( {y}_{k + 1} - {\hat{y}}_{k + 1 \vert k} ) & ( 13 )\end{matrix}$$

A current integration model that uses the following expressions in Expressions (2) and (3) is assumed here, and SOC is estimated by the Kalman filter:

$$\begin{matrix}[ Math . 2 ] & \\ f ( x ) = x & ( 14 ) \\ {b}_{u} ( u ) = \frac{τ}{{FCC}_{a}} {u}_{1} & ( 15 ) \\ h ( x , u ) = \frac{x - {SOC}_{0}}{{u}_{2} - {SOC}_{0}} \\ where & ( 16 ) \\ x = {SOC}_{i} & ( 17 ) \\ y = SOH & ( 18 ) \\ u = [ \begin{matrix}{u}_{1} \\ {u}_{2}\end{matrix} ] = [ \begin{matrix}i \\ {SOC}_{v}\end{matrix} ] & ( 19 )\end{matrix}$$

Here, τ is the sampling period, and FCC₀ is the full charge capacity. The value of FCC₀ may be the design capacity (DC), i.e. the normal value of FCC when the battery B is new, or the value calculated by taking the degree of degradation into account.

In detail, the state of health estimation method for a battery according to Embodiment 1 proceeds as follows. The current integration method state of charge estimation unit 4 performs the operation of Expression (4), to calculate the pre-state estimate

\hat{x}_{k+1|k}

Next, the first correction value calculation unit 9 performs the operations of Expressions (5) to (12), to calculate the Kalman gain K and the error covariance P. The first correction value calculation unit 9 then multiplies the difference (corresponding to

(yₖ₊₁−ŷ_{k+1|k})

in Expression (13)) between SOH₂ and SOH₁ received from the first subtraction unit 8 by the Kalman gain K to calculate the first correction value (corresponding to

Kₖ₊₁(yₖ₊₁−ŷ_{k+1|k})

in Expression (13)), and supplies it to the current integration method state of charge estimation unit 4. The current integration method state of charge estimation unit 4 then performs the operation of Expression (13) to correct the pre-state estimate

\hat{x}_{k+1|k}

by adding the first correction value to it, thus calculating the post-state estimate

\hat{x}_{k+1|k+1}.

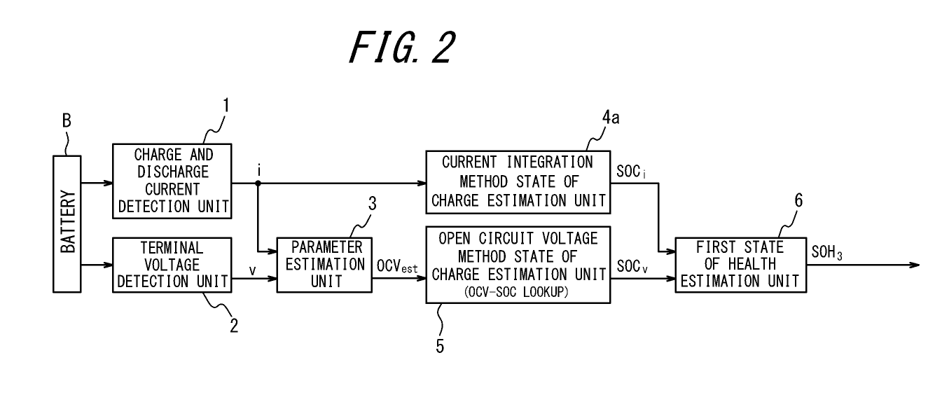

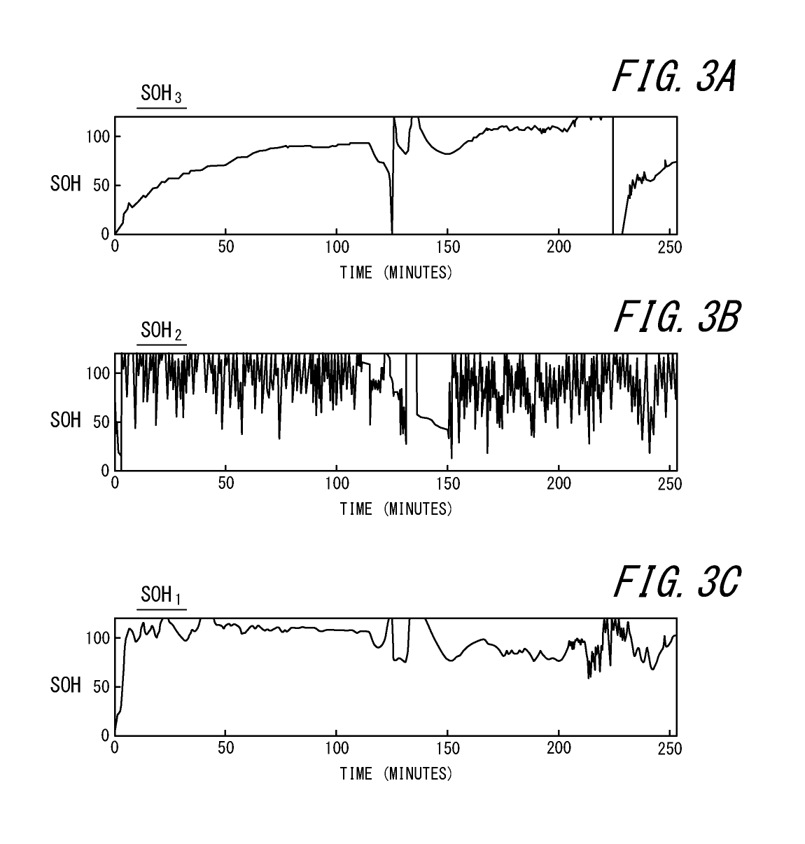

The result of simulation using the device for estimating state of health according to Embodiment 1 is described below, with reference to FIGS. 2 and 3.

FIG. 2 is a block diagram schematically illustrating the structure of a device for estimating state of health in which the second state of health estimation unit 7, the first subtraction unit 8, and the first correction value calculation unit 9 in the device for estimating state of health according to Embodiment 1 have been removed. A current integration method state of charge estimation unit 4a in the device for estimating state of health illustrated in FIG. 2 does not receive the first correction value from the first correction value calculation unit 9, and so integrates the charge and discharge current i to estimate the current integration method state of charge SOCᵢ without correcting the value of SOCᵢ. Accordingly, measurement errors by the charge and discharge current detection unit and the like have accumulated in SOCᵢ estimated by the current integration method state of charge estimation unit 4a, unlike SOCᵢ estimated by the current integration method state of charge estimation unit 4 illustrated in FIG. 1. The first state of health output from the device for estimating state of health illustrated in FIG. 2 is denoted by SOH₃.

FIG. 3(a) is a diagram illustrating the simulation result of SOH₃ estimated by the device for estimating state of health illustrated in FIG. 2. Errors accumulate in SOH₃ and gradually increase with time. FIG. 3(b) is a diagram illustrating the simulation result of SOH₂ estimated by the device for estimating state of health according to Embodiment 1. SOH₂ is unstable due to noise. FIG. 3(c) is a diagram illustrating the simulation result of SOH₁ estimated by the device for estimating state of health according to Embodiment 1. SOH₁ is more stable than SOH₂, demonstrating that the state of health SOH can be accurately estimated.

Thus, according to Embodiment 1, the current integration method state of charge estimation unit 4 estimates the current integration method state of charge SOCᵢ, and the open circuit voltage method state of charge estimation unit 5 estimates the open circuit voltage method state of charge SOCᵥ. The first state of health estimation unit 6 estimates the first state of health SOH₁ based on SOCᵢ and SOCᵥ, that is, from the ratio of the amount of change of SOCᵢ and the amount of change of SOCᵥ. The second state of health estimation unit 7 estimates the second state of health SOH₂ based on the relationship between the internal resistance value and state of health of the battery B, using the internal resistance value of the battery B estimated by the parameter estimation unit 3. The first correction value calculation unit 9 calculates the first correction value by multiplying the difference between SOH₂ and SOH₁ by the Kalman gain K, and the current integration method state of charge estimation unit 4 corrects SOCᵢ by adding the first correction value to it. By correcting SOCᵢ estimated by the current integration method state of charge estimation unit 4 in this way, the estimation accuracy of SOCᵢ can be improved to improve the estimation accuracy of SOH₁ estimated using SOCᵢ.

Moreover, according to Embodiment 1, the parameter estimation unit 3 estimates the open circuit voltage value OCVₑₛₜ of the battery from the equivalent circuit model of the battery B, using the charge and discharge current value i and terminal voltage value v received respectively from the charge and discharge current detection unit 1 and terminal voltage detection unit 2. The open circuit voltage method state of charge estimation unit 5 estimates the open circuit voltage method state of charge SOCᵥ based on the relationship between the open circuit voltage value and the state of charge, using OCVₑₛₜ estimated by the parameter estimation unit 3. By estimating the open circuit voltage value of the battery and estimating SOCᵥ using the estimated open circuit voltage value in this way, the estimation accuracy of SOCᵥ can be improved to improve the estimation accuracy of SOH₁ estimated using SOCᵥ.

### Embodiment 2

The following describes a device for estimating state of health according to Embodiment 2.

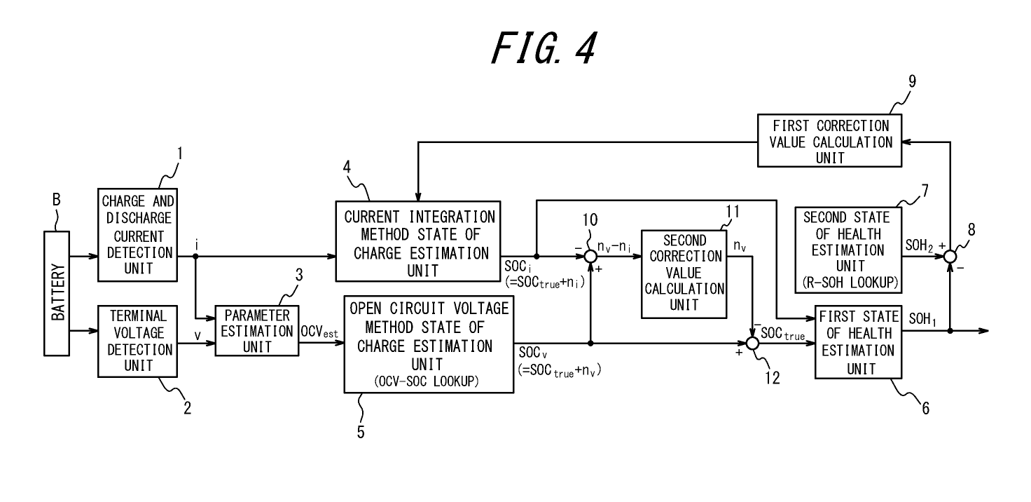

FIG. 4 is a block diagram schematically illustrating the structure of a device for estimating state of health according to Embodiment 2. The same structural elements as those in Embodiment 1 are given the same reference signs, and their description is omitted. The device for estimating state of health according to Embodiment 2 differs from Embodiment 1 in that a second subtraction unit 10, a second correction value calculation unit 11, and a third subtraction unit 12 are further included. An overview of the device for estimating state of health according to Embodiment 2 is as follows. The second correction value calculation unit 11 calculates a second correction value for correcting SOCᵥ based on the difference between the current integration method state of charge SOCᵢ and the open circuit voltage method state of charge SOCᵥ, and the third subtraction unit 12 corrects SOCᵥ using the second correction value.

The second subtraction unit 10 subtracts SOCᵢ obtained by the current integration method state of charge estimation unit 4 from SOCᵥ obtained by the open circuit voltage method state of charge estimation unit 5. Here, SOCᵢ obtained by the current integration method state of charge estimation unit 4 is the value of the true state of charge SOCₜᵣᵤₑ on which an estimation error (noise) nᵢ is superimposed, and SOCᵥ estimated by the open circuit voltage method state of charge estimation unit 5 is the value of the true state of charge SOCₜᵣᵤₑ on which an estimation error (noise) nᵥ is superimposed. Hence, the result of subtraction by the second subtraction unit 10 is SOCᵥ−SOCᵢ=nᵥ−nᵢ, where only the estimation error component remains.

The second correction value calculation unit 11 calculates the second correction value, by multiplying the difference (SOCᵥ−SOCᵢ=nᵥ−nᵢ) of the state of charge received from the second subtraction unit 10 by the Kalman gain. The process of calculating the second correction value will be described in detail later.

The third subtraction unit 12 subtracts the second correction value from SOCᵥ estimated by the open circuit voltage method state of charge estimation unit 5 to correct SOCᵥ, and supplies the corrected SOCᵥ to the first state of health estimation unit 6.

The process of calculating the second correction value and the process of correcting SOCᵥ are described below. These processes use, for example, the Kalman filter. In detail, an error model that uses the following expressions in Expressions (2) and (3) is assumed here, and nᵥ is estimated by the Kalman filter.

$$\begin{matrix}[ Math . 3 ] & \\ f = [ \begin{matrix}1 & 0 \\ 0 & 1\end{matrix} ] & ( 20 ) \\ {b}_{s} = 0 & ( 21 ) \\ h = [ - 1 \; 1 ] \\ where & ( 22 ) \\ x = [ \begin{matrix}{n}_{i} \\ {n}_{v}\end{matrix} ] & ( 23 ) \\ y = {SOC}_{v} - {SOC}_{i} = {n}_{v} - {n}_{i} & ( 24 ) \\ u = 0 & ( 25 )\end{matrix}$$

In detail, the state of health estimation method for a battery according to Embodiment 2 proceeds as follows. The second correction value calculation unit 11 performs the operations of Expressions (4) to (13), to calculate the Kalman gain K, the error covariance P, and the post-state estimate

\hat{x}_{k+1|k+1}

Here, the second correction value calculation unit 11 performs the operation of Expression (13) using the difference (corresponding to

yₖ₊₁

in Expression (13)) between SOCᵥ and SOCᵢ received from the second subtraction unit 10 to calculate, as the second correction value, the value of the post-state estimate

x_{k+1|k+1}

i.e. the estimated value of nᵥ, and supplies it to the third subtraction unit 12. The third subtraction unit 12 subtracts the second correction value from SOCᵥ estimated by the open circuit voltage method state of charge estimation unit 5 to correct SOCᵥ, and supplies high-accuracy SOCᵥ closer to the true state of charge SOCₜᵣᵤₑ to the first state of health estimation unit 6.

Thus, according to Embodiment 2, the second correction value calculation unit 11 calculates the second correction value for correcting the open circuit voltage method state of charge SOCᵥ, based on the difference between the current integration method state of charge SOCᵢ and the open circuit voltage method state of charge SOCᵥ. The third subtraction unit 12 subtracts the second correction value from SOCᵥ to correct SOCᵥ. In this way, the estimation accuracy of SOCᵥ estimated by the open circuit voltage method state of charge estimation unit 5 can be improved to further improve the estimation accuracy of SOH₁ estimated using SOCᵥ.

### Modification 1

The following describes Modification 1 to the embodiments.

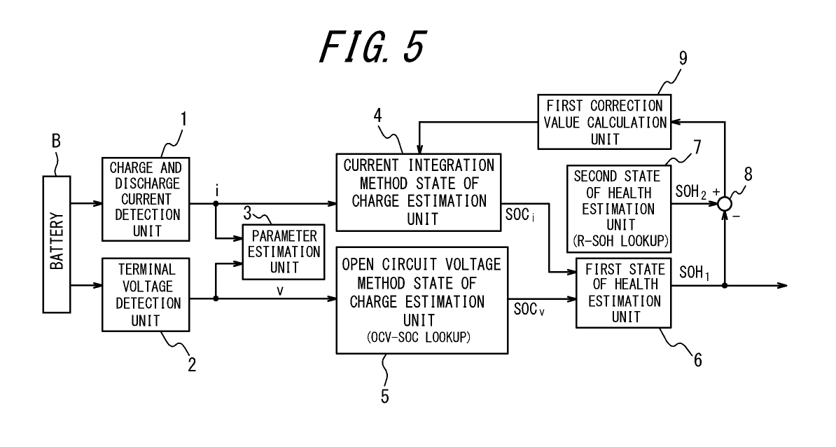

FIG. 5 is a block diagram schematically illustrating the structure of a device for estimating state of health according to Modification 1. The same structural elements as those in Embodiment 1 are given the same reference signs, and their description is omitted. The device for estimating state of health according to Modification 1 differs from Embodiments 1 and 2 in that the terminal voltage value v detected by the terminal voltage detection unit 2 is supplied to the open circuit voltage method state of charge estimation unit 5.

Thus, according to Modification 1 to the embodiments, the open circuit voltage method state of charge estimation unit 5 estimates the open circuit voltage method state of charge SOCᵥ using, as the open circuit voltage value OCV, the terminal voltage value v received from the terminal voltage detection unit 2. Since the parameter estimation unit 3 does not need to estimate the open circuit voltage value OCVₑₛₜ, the state of health can be estimated with reduced processing load.

### Modification 2

The following describes Modification 2 to the embodiments.

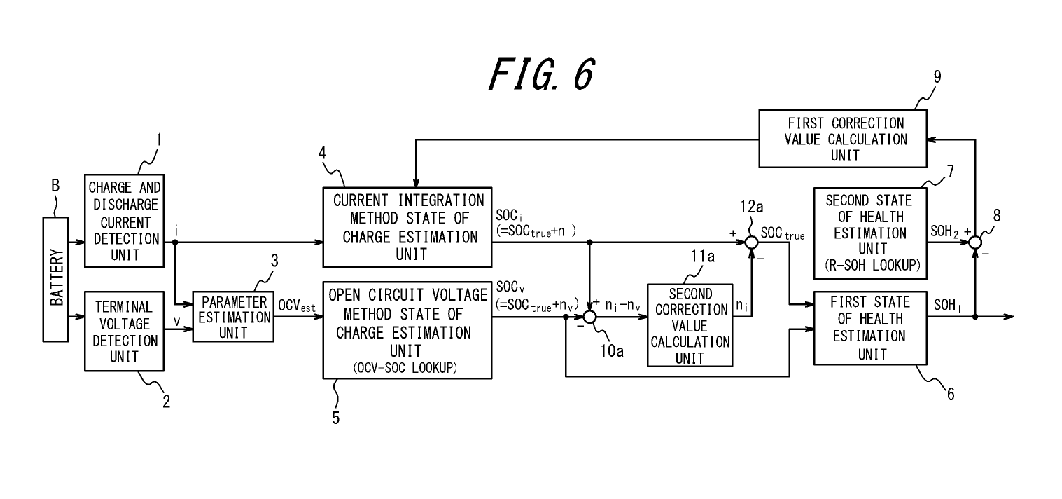

FIG. 6 is a block diagram schematically illustrating the structure of a device for estimating state of health according to Modification 2. The same structural elements as those in Embodiment 2 are given the same reference signs, and their description is omitted. The device for estimating state of health according to Modification 2 differs from Embodiment 2 in that a second correction value calculation unit 11a calculates nᵢ as a second correction value for correcting SOCᵢ estimated by the current integration method state of charge estimation unit 4, and a third subtraction unit 12a corrects SOCₒ using the second correction value.

The calculation of the second correction value in Modification 2 can be performed by the same process as in Embodiment 2. In detail, an error model that uses the following expressions in Expressions (2) and (3) is assumed here, and nᵢ is estimated by the Kalman filter.

$$\begin{matrix}[ Math . 4 ] & \\ f = [ \begin{matrix}1 & 0 \\ 0 & 1\end{matrix} ] & ( 26 ) \\ {b}_{s} = 0 & ( 27 ) \\ h = [ 1 - 1 ] \\ where & ( 28 ) \\ x = [ \begin{matrix}{n}_{i} \\ {n}_{v}\end{matrix} ] & ( 29 ) \\ y = {SOC}_{i} - {SOC}_{v} = {n}_{i} - {n}_{v} & ( 30 ) \\ u = 0 & ( 31 )\end{matrix}$$

Thus, according to Modification 2, the second correction value calculation unit 11a calculates the second correction value for correcting the current integration method state of charge SOCᵢ, based on the difference between the current integration method state of charge SOCᵢ and the open circuit voltage method state of charge SOCᵥ. The third subtraction unit 12a subtracts the second correction value from SOCᵢ to correct SOCᵢ. In this way, the estimation accuracy of SOCᵢ estimated by the current integration method state of charge estimation unit 4 can be improved to further improve the estimation accuracy of SOH₁ estimated using SOCᵢ.

Although the disclosed device and method have been described by way of the drawings and examples, various changes and modifications may be easily made by those of ordinary skill in the art based on this disclosure. Such various changes and modifications are therefore included in the scope of this disclosure. For example, the functions included in the means, steps, etc. may be rearranged without logical inconsistency, and a plurality of means, steps, etc. may be combined into one means, step, etc. and a means, step, etc. may be divided into a plurality of means, steps, etc.

For example, although the Kalman filter is used to estimate the state quantity in the foregoing embodiments, the state quantity may be estimated using other adaptive filters.

Moreover, a temperature detection unit for detecting the temperature of the battery may be further included to supply the detected temperature of the battery to the parameter estimation unit 3. In this case, the parameter estimation unit 3 estimates each parameter in the equivalent circuit model of the battery, based on the charge and discharge current value i, the terminal voltage value v, and the battery temperature.

### REFERENCE SIGNS LIST

B battery

1 charge and discharge current detection unit

2 terminal voltage detection unit

3 parameter estimation unit

4, 4a current integration method state of charge estimation unit (first state of charge estimation unit)

5 open circuit voltage method state of charge estimation unit (second state of charge estimation unit)

6 first state of health estimation unit

7 second state of health estimation unit

8 first subtraction unit

9 first correction value calculation unit

10, 10a second subtraction unit

11, 11a second correction value calculation unit

12, 12a third subtraction unit

1. A device for estimating state of health of a battery, comprising:
a charge and discharge current detection unit configured to detect a charge and discharge current value of the battery;
a terminal voltage detection unit configured to detect a terminal voltage value of the battery;
a first state of charge estimation unit configured to estimate a first state of charge by integrating the charge and discharge current value;
a second state of charge estimation unit configured to estimate a second state of charge based on a relationship between an open circuit voltage value and a state of charge of the battery;
a first state of health estimation unit configured to estimate a first state of health based on the first state of charge and the second state of charge;
a second state of health estimation unit configured to estimate a second state of health based on a relationship between an internal resistance value and a state of health of the battery; and
a first correction value calculation unit configured to calculate a first correction value for correcting the first state of charge, based on a difference between the first state of health and the second state of health,
wherein the first state of charge estimation unit is configured to correct the first state of charge using the first correction value.

2. The device for estimating state of health according to claim 1, further comprising
a second correction value calculation unit configured to calculate a second correction value for correcting the first state of charge or the second state of charge, based on a difference between the first state of charge and the second state of charge.

3. The device for estimating state of health according to claim 1, further comprising
a parameter estimation unit configured to estimate the open circuit voltage value of the battery from an equivalent circuit model of the battery, using the charge and discharge current value and the terminal voltage value,
wherein the second state of charge estimation unit is configured to estimate the second state of charge based on the relationship between the open circuit voltage value and the state of charge, using the estimated open circuit voltage value.

4. The device for estimating state of health according to claim 2, further comprising
a parameter estimation unit configured to estimate the open circuit voltage value of the battery from an equivalent circuit model of the battery, using the charge and discharge current value and the terminal voltage value,
wherein the second state of charge estimation unit is configured to estimate the second state of charge based on the relationship between the open circuit voltage value and the state of charge, using the estimated open circuit voltage value.

5. The device for estimating state of health according to claim 1,
wherein the second state of charge estimation unit is configured to estimate the second state of charge based on the relationship between the open circuit voltage value and the state of charge, using the terminal voltage value.

6. The device for estimating state of health according to claim 2,
wherein the second state of charge estimation unit is configured to estimate the second state of charge based on the relationship between the open circuit voltage value and the state of charge, using the terminal voltage value.

7. A state of health estimation method for a battery, comprising:
detecting a charge and discharge current value of the battery;
detecting a terminal voltage value of the battery;
estimating a first state of charge by integrating the charge and discharge current value;
estimating a second state of charge based on a relationship between an open circuit voltage value and a state of charge of the battery;
estimating a first state of health based on the first state of charge and the second state of charge;
estimating a second state of health based on a relationship between an internal resistance value and a state of health of the battery;
calculating a first correction value for correcting the first state of charge, based on a difference between the first state of health and the second state of health; and
correcting the first state of charge using the first correction value.
